(19) United States
(12) Patent Application Publication
(10) Pub. No.: US 2026/0278211 A1
(43) Pub. Date: Sep. 17, 2026

(54) Text-to-CAD Generation Using Fine-Tuned Large Language Models with Universal Text Representation and Its Encoder and Decoder Tool

(71) Applicant: gNucleus AI, Inc, Cupertino, CA (US)

(72) Inventor: Yu Xia, Cupertino, CA (US)

(73) Assignee: gNucleus AI, Inc, Cupertino, CA (US)

(21) Appl. No.: 19/080,850

(22) Filed: Mar. 15, 2025

(51) Int. Cl. G06F 30/27; G06F 30/12; G06F 40/20

(52) U.S. Cl. CPC G06F 30/27; G06F 30/12; G06F 40/20

(57) ABSTRACT

The present disclosure relates to a system and method for generating Computer-Aided Design (CAD) models from natural language descriptions utilizing Large Language Models (LLMs). A universal text-based representation of CAD models is provided, encoding complete Boundary Representation (B-Rep) information. A pre-trained LLM is fine-tuned using a dataset comprising paired natural language descriptions of CAD model creation processes and corresponding universal text-based representations. The fine-tuned LLM converts natural language descriptions into the universal text-based representations, which are subsequently converted into CAD models. The system incorporates solver-based grounding to ensure geometric and topological accuracy and employs Reinforcement Learning from Human Feedback (RLHF) to refine model alignment with expert-defined best practices. An encoder/decoder tool facilitates lossless conversion between the text-based representation and native CAD software formats, streamlining CAD model generation with high precision and adaptability.

### PRIOR ART

R. Wu, C. Xiao, and C. Zheng, “Deepcad: A deep generative network for computer-aided design models,” in Proceedings of the IEEE/CVF International Conference on Computer Vision (ICCV), October 2021, pp. 6772–6782. This paper, DeepCAD, models CAD models as sequences of CAD commands in CAD softwares, such as sketching and extrusion, and employs a Transformer-based autoencoder trained from scratch on a dataset of CAD model and command sequences. It learns a 256-dimensional latent vector space where CAD models are embedded, and generation is achieved by decoding a latent vector into a sequence of CAD commands. The CAD command sequences are CAD software dependent. In contrast, the disclosed invention translates natural language descriptions into a universal text-based representation encoding complete Boundary Representation (B-Rep) information, which can be reconstructed into any native CAD format. It fine-tunes a pre-trained Large Language Model (LLM) using paired natural language and CAD data, allowing for direct text-to-CAD model generation. Additionally, DeepCAD does not incorporate explicit grounding mechanisms to enforce geometric and topological constraints, whereas the disclosed invention ensures accuracy through grounding techniques and improves model alignment with best practices using Reinforcement Learning from Human Feedback (RLHF). Thus, while DeepCAD focuses on learning CAD command sequences through latent space encoding, the disclosed system uniquely enables natural language-driven CAD generation with universal structured B-Rep encoding, interoperability with native CAD formats, and reinforcement learning to enhance model reliability.

M. S. Khan, S. Sinha, T. U. Sheikh, D. Stricker, S. A. Ali, and M. Z. Afzal, “Text2cad: Generating sequential cad models from beginner-to-expert level text prompts,” 2024. [Online]. Available: https://arxiv.org/abs/2409.17106. Text2CAD models CAD models as sequences of CAD commands, leveraging the DeepCAD dataset with annotated natural language prompts and using a transformer-based autoregressive model where inputs are tokenized and encoded via a pre-trained BERT model. In contrast, the disclosed invention introduces a universal text-based representation that encodes complete Boundary Representation (B-Rep) information, enabling seamless conversion to native CAD formats. While Text2CAD translates text into CAD commands, it does not fine-tune a pre-trained Large Language Model (LLM) but instead maps text embeddings to CAD sequences, whereas the disclosed system fine-tunes an LLM with paired natural language and structured CAD representations. Additionally, Text2CAD does not incorporate Reinforcement Learning from Human Feedback (RLHF), whereas the disclosed invention uses RLHF to improve CAD model accuracy and adherence to best practices. A major limitation of Text2CAD is that it supports only sketch and extrude operations, whereas the disclosed system supports all CAD operations, making it significantly more versatile. While Text2CAD contributes to text-to-CAD generation, it does not anticipate the structured B-Rep encoding, full CAD interoperability, or reinforcement learning techniques of the disclosed system.

J. Xu, C. Wang, Z. Zhao, W. Liu, Y. Ma, S. Gao, “Unifying Multimodality-Conditioned CAD Generation With MLLM”, 2024. [Online]. Available: https://arxiv.org/abs/2411.04954. CAD-MLLM generates parametric CAD models from multimodal inputs, including text, images, and point clouds, aligning feature spaces to CAD command sequences, whereas the disclosed system introduces a universal text-based representation encoding complete Boundary Representation (B-Rep) information for precise geometric and topological modeling. While CAD-MLLM trains an LLM on multimodal CAD data, it does not specifically fine-tune a model for text-to-CAD translation, whereas the disclosed system fine-tunes a pre-trained LLM using paired natural language and structured CAD representations, ensuring accurate text-driven CAD generation. Additionally, CAD-MLLM lacks explicit Reinforcement Learning from Human Feedback (RLHF) and grounding mechanisms for geometric accuracy, while the disclosed system incorporates RLHF to align with expert modeling practices and employs grounding techniques to enforce geometric and topological constraints. The main distinctions lie in CAD-MLLM's reliance on multimodal feature alignment versus the disclosed system’s structured B-Rep encoding, fine-tuned LLM integration, and reinforcement learning to enhance CAD model generation accuracy and interoperability.

### BACKGROUND OF THE INVENTION

Large Language Models (LLMs) have demonstrated a remarkable ability to understand and generate human-like text, learning intricate patterns from massive datasets.

While proficient in generating coherent and contextually relevant text, LLMs may not inherently produce text in highly specialized formats, such as those required for Computer-Aided Design (CAD). Fine-tuning techniques address this limitation by training LLMs on examples conforming to a specific domain or format, thereby tailoring the model's output.

CAD models are accurate digital representations of physical objects or systems, created using specialized software. These models are fundamental to modern design and manufacturing, enabling engineers, architects, and designers to create detailed, precise, and modifiable representations of products or structures prior to physical prototyping.

Boundary representation (B-Rep) is a common method employed in CAD to define the shape and structure of a solid object by its bounding faces. Instead of directly describing the object's body, B-Rep represents it using a combination of topological (bodies, connectivity of faces, edges, and vertices) and geometric (precise mathematical descriptions of surfaces and curves) information. This approach allows for the accurate capture of intricate topological and geometric details, making B-Rep models suitable for complex designs.

Geometric constraint solvers in CAD software play a critical role in ensuring geometric and parametric consistency by automatically resolving constraints and dependencies within a design. These solvers operate by interpreting user-defined constraints—such as dimensions, geometric relationships (e.g., tangency, perpendicularity, symmetry), and assembly constraints—and dynamically adjusting the model to maintain these conditions.

### SUMMARY OF THE INVENTION

This patent describes a system for generating Computer-Aided Design (CAD) models directly from natural language descriptions using fine-tuned Large Language Models (LLMs). The core innovation is a universal text-based representation of CAD models, encoding complete Boundary Representation (B-Rep) information (bodies, faces, edges, vertices) in a human-readable format. A paired dataset of natural language CAD creation instructions and corresponding text-based representations is used to fine-tune a pre-trained LLM. A solver-based grounding mechanism validates the generated models, enforcing geometric and topological consistency, while Reinforcement Learning from Human Feedback (RLHF) iteratively refines model performance based on expert feedback. A universal encoder/decoder tool enables lossless conversion between the text representation and native CAD software formats, ensuring broad applicability across different CAD platforms.

### BRIEF DESCRIPTION OF DRAWINGS

FIG. 1 is a block diagram illustrating an exemplary system and method for fine-tuning a Large Language Model (LLM) to generate Computer-Aided Design (CAD) models from natural language descriptions. The diagram depicts the overall workflow, encompassing data generation, model fine-tuning, and refinement processes.

Specifically, FIG. 1 illustrates the generation of natural language descriptions (102) and a universal text-based CAD representation (103) from a CAD model (101). These outputs serve as input (104) and target (105) data for supervised fine-tuning (106) of a pre-trained LLM (107), resulting in a CAD GenAI Model (108). Further refinement of the CAD GenAI Model (108) is shown through a reinforcement learning process incorporating grounding by a geometric constraint solver (109), human evaluation (110), and a reward model (111).

FIG. 2 is a block diagram depicting the conversion process between a universal text-based Computer-Aided Design (CAD) representation and a CAD model in a native CAD software format. The diagram illustrates an encoder (202) receiving a universal text-based CAD representation (201) and generating an encoded CAD representation (203). Conversely, the diagram shows a decoder (204), specific to each CAD software, receiving the encoded CAD representation (203) and reconstructing the CAD model in the corresponding CAD software format (204).

FIG. 3 is a block diagram illustrating the inference process for generating a Computer-Aided Design (CAD) model from a user's natural language description. The diagram depicts a user providing a natural language description (301) of a desired CAD model, which serves as input to a model inference stage (302) utilizing a CAD GenAI Model (303) fine-tuned according to the system and method illustrated in FIG. 1. The output of the model inference stage (302) is a universal text-based representation of the CAD model (304). This representation is then processed through a grounding by solver stage (305) and an encoder/decoder stage (306) to produce a final CAD model (307). The figure demonstrates the end-to-end process of translating natural language descriptions into functional CAD models through the application of a trained generative AI model and subsequent refinement processes.

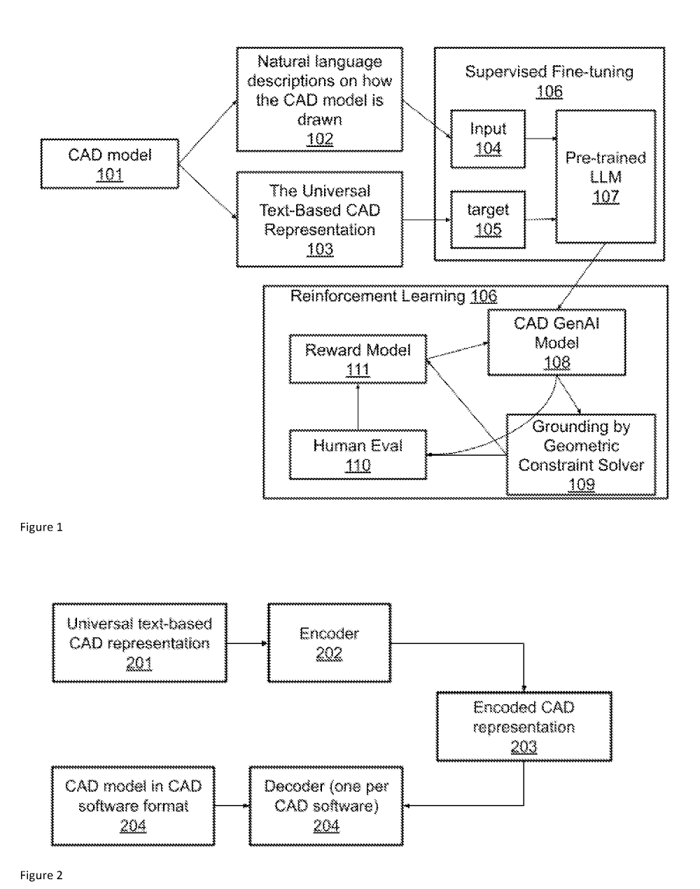

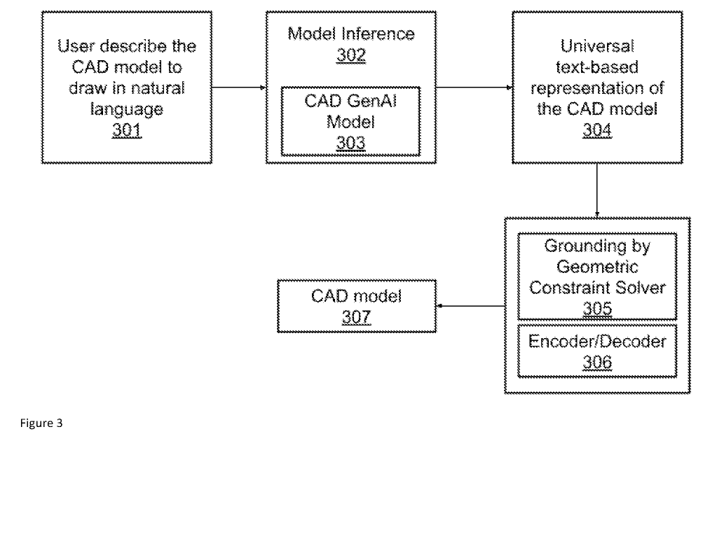

### DETAILED DESCRIPTION OF THE INVENTION

Disclosed implementations provide a universal text-based representation of a CAD model for training an LLM in a Text-to-CAD generation task. This representation is a human-readable and comprehensive text format encoding complete CAD model information, enabling conversion back to any B-Rep-supporting native CAD format. To capture B-Rep elements, the representation includes definitions for all key solid model components: bodies, faces, edges, and vertices. These definitions encompass topological relationships, geometric definitions with associated curves or surfaces, and precise coordinates or parameters defining critical points for vertices. This representation incorporates CAD consistency rules so each different CAD format can be mapped into the same text space. The text format is sufficiently general to capture diverse CAD models, ranging from simple parts to complex assemblies, while remaining readily interpretable by downstream encoder and decoder tools. The format is structured using protocol buffer language for ease of parsing and debugging.

A dataset pairing natural language descriptions of the CAD creation process with corresponding universal text-based representations is generated as follows:

Input Data (Natural Language Descriptions): Detailed, step-by-step natural language descriptions are created, outlining the process of drawing a CAD model. These descriptions include specifications such as design parameters, dimensions, geometric constraints, and design-specific instructions. For example, a description might state, "Draw a rectangle with a length of 100 units and a width of 50 units, then extrude it to a height of 20 units. Create a fillet of 5 units on all edges of the top face."

Target Data (Universal Text-Based CAD Representation): For each natural language description, a corresponding text-based representation encoding the full B-Rep information is generated manually or semi-automatically. This representation includes structured entries for all bodies, faces, edges, and vertices, along with metadata such as dimensions, connectivity, and any parametric relationships and constraints.

Data Pairing: The data is organized into paired examples, with each natural language description matched to its corresponding universal text-based CAD model. These pairs constitute the training dataset.

This dataset is used to fine-tune a pre-trained LLM (e.g., ChatGPT, Gemini, LLaMA). The fine-tuned LLM converts natural language descriptions directly into the defined universal text-based CAD model representation.

Pre-Training Base: The process begins with a pre-trained LLM possessing strong natural language understanding and generation capabilities.

Supervised Fine-Tuning: The paired dataset is used to fine-tune the LLM, enabling it to map procedural language inputs to the structured CAD model representation. The training objective is to minimize the difference between the generated and target representations.

Evaluation and Iteration: The fine-tuned model is tested on unseen natural language descriptions to ensure accurate and complete CAD representation generation. The dataset and fine-tuning parameters are iteratively refined to improve accuracy, consistency, and the model's ability to handle diverse design instructions.

Grounding Process: To ensure both topological and geometrical accuracy, a grounding process using CAD tooling (e.g., a geometric constraint solver) corrects imperfect or inaccurate results. For example, the grounding process can ensure that face boundaries form closed edge loops.

Reinforcement Learning from Human Feedback (RLHF): RLHF further refines the model, ensuring alignment with expert-defined CAD modeling best practices.

Human Feedback Collection: Experts review generated CAD representations and provide feedback regarding correctness, completeness, and usability.

Reward Model Training: A reward model is trained using human feedback to score the quality of generated CAD representations.

Fine-Tuning with RLHF: The LLM is fine-tuned using reinforcement learning techniques (e.g., Proximal Policy Optimization).

Iterative Improvement: The RLHF pipeline continuously incorporates feedback, refining the model over time.

Encoder: The encoder tool extracts geometric and topological data, and step-by-step modeling history with dimensions, sorting the representation by geometry and topological attributes, and assigning a natural language naming to all the geometric and topological attributes. This tool could be implemented as a distributed batch job on the cloud for processing large datasets.

Decoder: The decoder tool maps the encoded elements into native CAD software data structures, reconstructing B-Rep information and modeling steps. This tool could be served as a cloud service for real-time decoding and is one decoder per CAD software.

Validation: The converted CAD model is validated within the target CAD software.

This approach creates a natural language-to-CAD model AI system, streamlining the design workflow by bridging the gap between human instructions and machine-interpretable CAD models, facilitating design automation and rapid prototyping.

1. A method for generating a Computer-Aided Design (CAD) model from a natural language description, comprising:
a. Receiving a natural language description of a CAD model;
b. Generating a universal text-based representation of the CAD model, the universal text-based representation encoding Boundary Representation (B-Rep) information of the CAD model;
c. Fine-tuning a pre-trained Large Language Model (LLM) using a dataset comprising paired natural language descriptions of CAD model creation processes and corresponding universal text-based representations, wherein the fine-tuned LLM is configured to generate the universal text-based representation from a natural language description;
d. Generating the universal text-based representation of the CAD model from the natural language description using the fine-tuned LLM;
e. Grounding the universal text-based representation using a geometric constraint solver to ensure geometric and topological consistency;
f. Converting the grounded universal text-based representation into a CAD model in a native CAD software format using an encoder/decoder tool;
g. Refining the fine-tuned LLM using Reinforcement Learning from Human Feedback (RLHF) to align CAD model generation with expert best practices.

2. A system for generating a Computer-Aided Design (CAD) model from a natural language description, the system comprising:
a. A processor;
b. A non-transitory storage medium storing executable instructions, wherein the processor executes the instructions to:
i. Receive a natural language description of a CAD model;
ii. Generate a universal text-based representation encoding complete Boundary Representation (B-Rep) information of the CAD model;
iii. Fine-tune a pre-trained Large Language Model (LLM) using a dataset of paired natural language descriptions and universal text-based CAD representations to improve text-to-CAD conversion accuracy;
iv. Generate the universal text-based representation of the CAD model using the fine-tuned LLM;
v. Ground the universal text-based representation using a geometric constraint solver to ensure geometric validity, topological correctness, and constraint satisfaction;
vi. Convert the universal text-based representation into a native CAD software format using an encoder/decoder tool;
vii. Train a reward model based on expert evaluations and apply Reinforcement Learning from Human Feedback (RLHF) to refine the fine-tuned LLM.

3. The method of claim 1, wherein the universal text-based representation comprises:
a. A structured format in protocol buffer language designed for ease of parsing and debugging;
b. Complete encoding of B-Rep topology, including structured entries for all bodies, faces, edges, and vertices;
c. Parametric relationships, geometric constraints, and metadata describing the CAD model.

4. The method of claim 1, wherein the grounding by a geometric constraint solver comprises:
a. Validating topological relationships between faces, edges, and vertices;
b. Ensuring geometric constraints such as tangency, perpendicularity, symmetry, and closed loops;
c. Correcting inconsistencies in the CAD model prior to encoding.

5. The method of claim 1, wherein the encoder/decoder tool comprises:
a. An encoder module that parses the text-based representation and extracts geometric and topological data;
b. A decoder module specific to native CAD software formats that maps the extracted data into CAD-native data structures;
c. Validation mechanisms to verify reconstruction fidelity within the CAD environment.

6. The method of claim 1, wherein the Reinforcement Learning from Human Feedback (RLHF) comprises:
a. Collecting human expert feedback on generated CAD representations;
b. Training a reward model using expert evaluations to score the quality of generated CAD representations;
c. Applying reinforcement learning techniques to iteratively improve the fine-tuned LLM.

7. The system of claim 2, wherein the system further comprises:
a. A cloud-based distributed processing pipeline for fine-tuning the LLM using large-scale datasets;
b. A real-time inference module that allows users to input natural language CAD descriptions and receive generated CAD models interactively;
c. A database storing generated CAD representations for further evaluation and refinement.

8. The method of claim 1, wherein the universal text-based representation supports conversion to multiple CAD formats, including:
a. Parametric CAD software native formats (like SolidWorks, Catia, NX, Creo, FreeCAD);
b. Neutral B-Rep CAD Exchange Formats (like Step, Iges, Parasolid X-T);
c. Polygonal mesh format (like STL, GLTF).

9. The method of claim 1, wherein the fine-tuned LLM is based on a Transformer-based architecture, including models such as:
a. ChatGPT, Gemini, or Claude;
b. Open-source LLMs like LLaMA, DeepSeek, QWen or Mistral.
